(19) United States
(12) Patent Application Publication
(10) Pub. No.: US 2026/0234399 A1
(43) Pub. Date: Aug. 13, 2026

(54) RESIN COMPOSITION AND USES OF THE SAME

(71) Applicant: TAIWAN UNION TECHNOLOGY CORPORATION, Zhubei City (TW)

(72) Inventor: Chun-Kai LIN, Zhubei City (TW)

(21) Appl. No.: 19/289,297

(22) Filed: Aug. 4, 2025

(30) Foreign Application Priority Data
Feb. 7, 2025 (TW) 114104552

(51) Int. Cl. C08L 79/08; B32B 15/08; C08J 5/24; C08K 5/357; C08L 79/04; H05K 1/03

(52) U.S. Cl. CPC C08L 79/085; B32B 15/08; C08J 5/244; C08J 5/249; C08K 5/357; C08L 79/04; B32B 2262/101; B32B 2457/08; C08J 2379/04; C08J 2379/08; C08J 2479/04; C08J 2479/08; H05K 1/0373

(57) ABSTRACT

A resin composition is provided. The resin composition includes (A) a bismaleimide resin, (B) a cyanate ester resin with a number average molecular weight ranging from 1000 to 3000, and (C) a benzoxazine compound. A prepreg prepared from the resin composition, a metal-clad laminate prepared from the prepreg and a printed circuit board prepared from the metal-clad laminate are also provided.

### CLAIM FOR PRIORITY

This application claims the benefit of Taiwan Patent Application No. 114104552 filed on Feb. 7, 2025, the subject matters of which are incorporated herein in their entirety by reference.

### BACKGROUND

### Field of the Invention

The present invention provides a resin composition, especially, a resin composition comprising a bismaleimide resin, a cyanate ester resin with a specific number average molecular weight (Mn), and a benzoxazine compound. The present invention also provides a prepreg, a metal-clad laminate, and a printed circuit board prepared from the resin composition.

### Descriptions of the Related Art

In response to the trend of technology development, electronic products are increasingly designed to provide high-frequency signal transmission, high-speed signal transmission, miniaturization, and high-density wirings. As a result, the requirements for the dielectric properties of the related electronic materials are rising increasingly higher, requiring a lower dielectric constant (Dk) and a lower dielectric dissipation factor (Df). Additionally, in the manufacture of printed circuit boards, lead-free processing is utilized due to environmental reasons, which requires higher processing temperatures. Thus, the requirements for thermal resistance of dielectric layer materials of printed circuit boards have increased.

In the prior art, a bismaleimide-based resin composition comprising a bismaleimide resin and a cyanate ester is commonly used as a dielectric layer material. However, although the bismaleimide-based resin composition possesses several advantages, such as a high glass transition temperature (Tg), high thermal resistance, moisture resistance, a low Dk and a low Df, laminates manufactured from the bismaleimide-based resin composition exhibit poor mechanical processing properties, which causes them perform poorly in current manufacturing processes.

Thus, there is still a need for an electronic material with a high upper limit for the number of drilled holes, a high Tg, and increased multiple hot-pressing thermal resistance, such that it is suitable for various high-frequency applications.

### SUMMARY

In view of the aforementioned technical problems, the present invention provides a resin composition, which comprises a bismaleimide resin, a cyanate ester resin with a specific number average molecular weight, and a benzoxazine compound. The resin composition of the present invention is therefore characterized in the combination of the cyanate ester resin with a specific number average molecular weight, the bismaleimide resin and the benzoxazine compound. Using the above specific combination, electronic materials obtained from the resin composition of the present invention can significantly improve their mechanical processing properties (as demonstrated by the “test of upper limit for the number of drilled holes”) and multiple hot-pressing thermal resistance without compromising their Tg and thermal resistance.

Thus, an objective of the present invention is to provide a resin composition, which comprises the following components:
(A) a bismaleimide resin;
(B) a cyanate ester resin with a number average molecular weight ranging from 1000 to 3000; and
(C) a benzoxazine compound.

In one embodiment of the present invention, the bismaleimide resin (A) has a structure represented by the following formula (I):

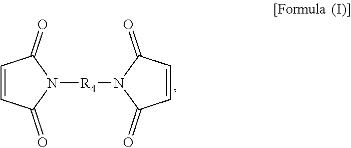

in formula (I), R₄ is selected from the group consisting of methylene (—CH₂—), 4,4′-diphenylmethane group

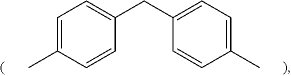

m-phenylene

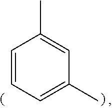

bisphenol A diphenyl ether group

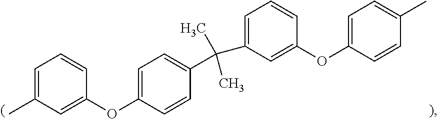

3,3′-dimethyl-5,5′-diethyl-4,4′ -diphenylmethane group

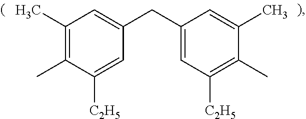

4-methyl-1,3-phenylene

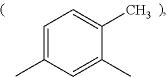

2,2,4-trimethyl-1,6-hexamethylene

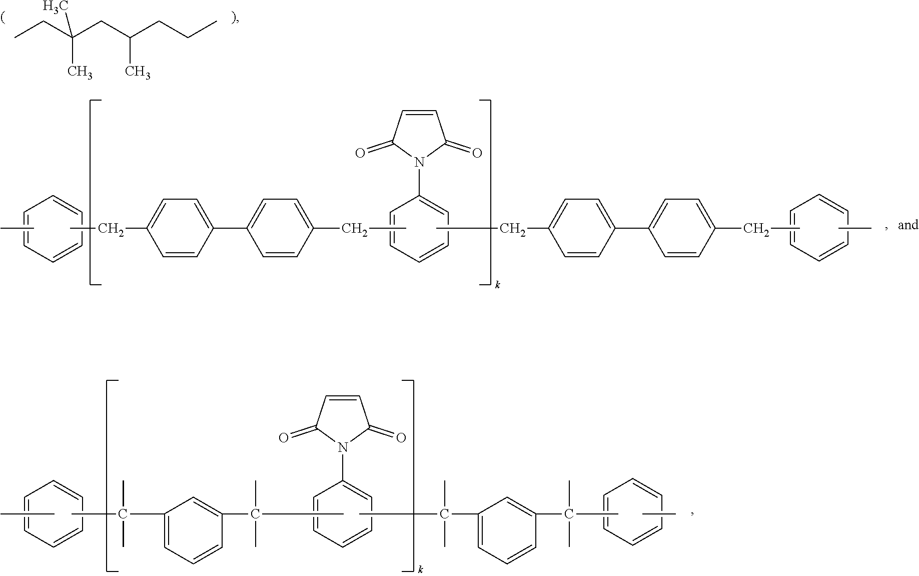

wherein k is an integer of 0 to 5.

In one embodiment of the present invention, the bismaleimide resin (A) is selected from the group consisting of 1,2-bismaleimidoethane, 1,6-bismaleimidohexane, 1,3-bismaleimidobenzene, 1,4-bismaleimidobenzene, 2,4-bismaleimidotoluene, 4,4′-bismaleimidodiphenylmethane, 4,4′-bismaleimidodiphenyl ether, 3,3′-bismaleimidodiphenyl sulfone, 4,4′-bismaleimidodiphenyl sulfone, 4,4′-bismaleimidodicyclohexylmethane, 3,5-bis(4-maleimidophenyl)pyridine, 2,6-bismaleimidopyridine, 1,3-bis(maleimidomethyl)cyclohexane, 1,3-bis(maleimidomethyl)benzene, 1,1-bis(4-maleimidophenyl)cyclohexane, 1,3-bis(dichloromaleimido)benzene, 4,4′-biscitraconimidodiphenylmethane, 2,2-bis(4-maleimidophenyl) propane, 1-phenyl-1,1-bis(4-maleimidophenyl) ethane, α,α-bis(4-maleimidophenyl) toluene, 3,5-bismaleimido-1,2,4-triazole, N,N′-ethylenebismaleimide, N,N′ -hexamethylenebismaleimide, N,N′-m-phenylenebismaleimide, N,N′-p-phenylenebismaleimide, N,N′-α,α′-4,4′-dimethylenecyclohexane bismaleimide, N,N′-m-dimethylphenylbismaleimide, N,N′-4,4′-diphenylcyclohexane bismaleimide,

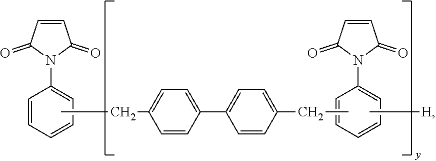

and combinations thereof,
wherein y is an integer of 1 to 4.

In one embodiment of the present invention, the cyanate ester resin (B) is selected from the group consisting of 2,2-bis(4-cyanooxyphenyl) propane, 4,4′-ethylidene bisphenylenecyanate, 4,4′-dicyanooxybiphenyl, bis(4-cyanooxy-3,5-dimethylphenyl) methane, bis(4-cyanooxyphenyl) sulfide, bis(4-cyanooxyphenyl) ether, a prepolymer of bisphenol A dicyanate ester, 1,1-bis(4-cyanooxyphenyl) ethane, 1,1-bis(4-cyanooxyphenyl) methane, 1,3-bis(4-cyanooxyphenyl-1-(methylethylidene))benzene, bis(4-cyanooxyphenyl) ether, bis(4-cyanooxyphenyl)-2,2-butane, 1,3-bis[2-(4-cyanooxyphenyl) propyl]benzene, tris(4-cyanooxyphenyl) ethane, cyanated phenol, an adduct of cyanated phenol dicyclopentadiene, and combinations thereof.

In one embodiment of the present invention, the resin composition further comprises a hardening accelerator selected from the group consisting of an imidazole compound, a pyridine compound, and a combination thereof.

In one embodiment of the present invention, the resin composition further comprises a hardener selected from the group consisting of styrene, α-methylstyrene, ethylstyrene, propylstyrene, butylstyrene, triallyl isocyanurate (TAIC), triallyl cyanurate (TAC), 1,3-divinylbenzene, 1,4-divinylbenzene, 1,2-bis(p-vinylphenyl) ethane, 1,2-bis(m-vinylphenyl) ethane, 1-(p-vinylphenyl)-2-(m-vinylphenyl) ethane, and combinations thereof.

In one embodiment of the present invention, the resin composition further comprises a filler selected from the group consisting of silica (including spherical silica, fused silica, non-fused silica, porous silica, hollow silica, and nano silica), aluminum oxide, magnesium oxide, magnesium hydroxide, calcium carbonate, talc, clay, aluminum nitride, boron nitride, aluminum hydroxide, silicon aluminum carbide, silicon carbide, sodium carbonate, titanium dioxide, zinc oxide, zirconium oxide, quartzes, diamond powder, diamond-like powder, graphite, calcined kaolin, pyran, mica, hydrotalcite, polytetrafluoroethylene (PTFE) powder, glass bead, ceramic whisker, carbon nanotube, nanosized inorganic powder, and combinations thereof.

Another objective of the present invention is to provide a prepreg, which is prepared by impregnating a substrate with the aforementioned resin composition or by coating the aforementioned resin composition onto a substrate and drying the impregnated or coated substrate.

Yet another objective of the present invention is to provide a metal-clad laminate, which is prepared by laminating the aforementioned prepreg and a metal foil.

Still another objective of the present invention is to provide a printed circuit board, which is prepared from the aforementioned metal-clad laminate.

To render the above objectives, technical features and advantages of the present invention more apparent, the present invention will be described in detail with reference to some embodiments hereinafter.

### BRIEF DESCRIPTION OF THE DRAWINGS

Not applicable.

### DETAILED DESCRIPTION

Hereinafter, some embodiments of the present invention will be described in detail. However, the present invention may be embodied in various embodiments and should not be limited to the embodiments described in the specification.

Unless otherwise specified, the expressions “a,” “the,” or the like recited in the specification and in the claims should include both the singular and the plural forms.

Unless otherwise specified, while describing the amount of the components in the solution, mixture, composition or varnish in the specification and in the claims, the weight of the solvent is not included.

As used herein, the unit of the “number average molecular weight (Mn)” is “dalton”.

The resin composition of the present invention comprises a bismaleimide resin, a cyanate ester resin with a specific number average molecular weight, and a benzoxazine compound. Through the synergistic effect of each of the components, an electronic material manufactured from the resin composition of the present invention can significantly improve its mechanical processing properties and also its multiple hot-pressing thermal resistance without compromising its high Tg and thermal resistance. Further details about the resin composition of the present invention and its applications are elaborated below.

### 1. Resin Composition

The resin composition of the present invention comprises (A) a bismaleimide resin, (B) a cyanate ester resin with a number average molecular weight ranging from 1000 to 3000, and (C) a benzoxazine compound as essential components, and other optional components. Further details about each component are elaborated below.

### 1.1. Bismaleimide Resin (A)

As used herein, a bismaleimide resin refers to a resin with at least two maleimide functional groups. The maleimide functional group refers to an unsaturated imide functional group having a reactive double bond (i.e., a carbon-carbon double bond). Due to the reactive double bond, any component that has the maleimide functional group can react with other components that has unsaturated groups. In one embodiment of the present invention, the bismaleimide resin (A) has a structure represented by the following formula (I):

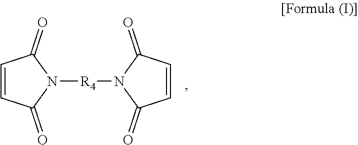

In formula (I), R₄ is selected from the group consisting of methylene (—CH₂—), 4,4′-diphenylmethane group

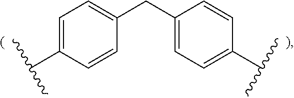 [SMILES: *c1ccc(Cc2ccc(*)cc2)cc1]

m-phenylene

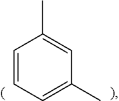

bisphenol A diphenyl ether group

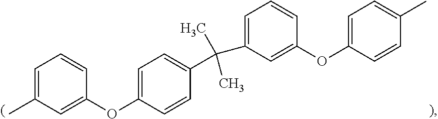

3,3′-dimethyl-5,5′-diethyl-4,4′-diphenylmethane group

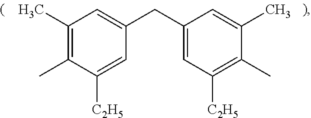

4-methyl-1,3-phenylene

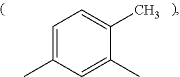

2,2,4-trimethyl-1,6-hexamethylene

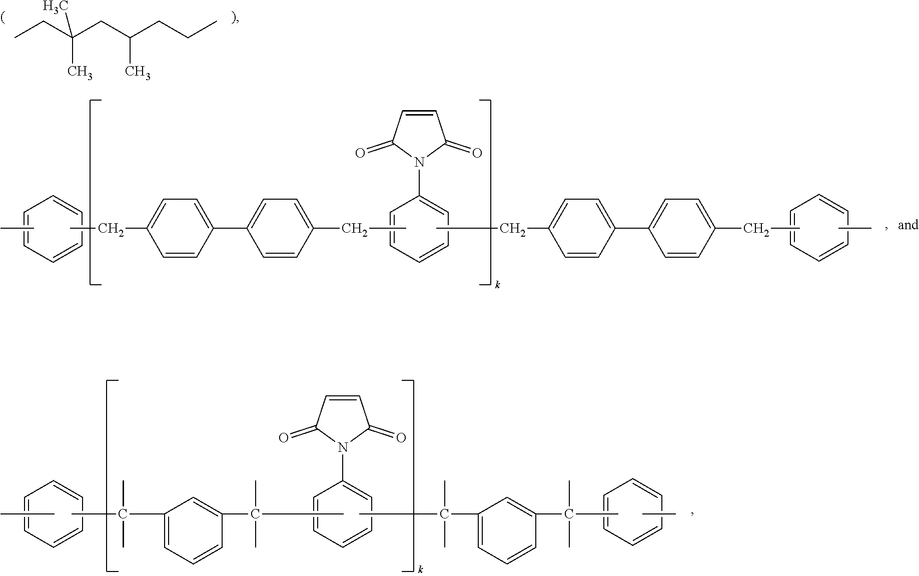

wherein k is an integer of 0 to 5.

Specific examples of the bismaleimide resin (A) that can be used in the resin composition of the present invention include, but are not limited to, 1,2-bismaleimidoethane, 1,6-bismaleimidohexane, 1,3-bismaleimidobenzene, 1,4-bismaleimidobenzene, 2,4-bismaleimidotoluene, 4,4′-bismaleimidodiphenylmethane, 4,4′-bismaleimidodiphenyl ether, 3,3′-bismaleimidodiphenyl sulfone, 4,4′-bismaleimidodiphenyl sulfone, 4,4′-bismaleimidodicyclohexylmethane, 3,5-bis(4-maleimidophenyl)pyridine, 2,6-bismaleimidopyridine, 1,3-bis(maleimidomethyl)cyclohexane, 1,3-bis(maleimidomethyl)benzene, 1,1-bis(4-maleimidophenyl)cyclohexane, 1,3-bis(dichloromaleimido)benzene, 4,4′-biscitraconimidodiphenylmethane, 2,2-bis(4-maleimidophenyl) propane, 1-phenyl-1,1-bis(4-maleimidophenyl) ethane, α,α-bis(4-maleimidophenyl) toluene, 3,5-bismaleimido-1,2,4-triazole, N,N′-ethylenebismaleimide, N,N′-hexamethylenebismaleimide, N,N′-m-phenylenebismaleimide, N,N′-p-phenylenebismaleimide, N,N′-α,α′-4,4′-dimethylenecyclohexane bismaleimide, N,N′-m-dimethylphenylbismaleimide, N,N′-4,4′-diphenylcyclohexane bismaleimide,

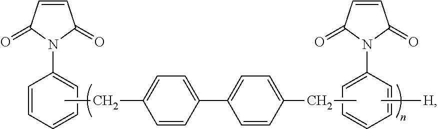

wherein y is an integer of 1 to 4. The aforementioned bismaleimide resins can be used individually or in a mixture of two or more.

Commercially available bismaleimide resins include, but are not limited to, products such as BMI-70 and BMI-80 available from KI Chemical, MIR-300-70MT available from Nippon Kayaku, and BMI-1000, BMI-2000, BMI-2300, BMI-4000, BMI-5000, BMI-5100 and BMI-7000 available from Daiwa Kasei Industry (Nihon, Wakayama).

In the resin composition of the present invention, based on 100 parts by weight of the total weight of the bismaleimide resin (A), the cyanate ester resin (B) and the benzoxazine compound (C) excluding solvent, the amount of the bismaleimide resin (A) can be 20 parts by weight to 80 parts by weight. For example, based on 100 parts by weight of the total weight of the bismaleimide resin (A), the cyanate ester resin (B) and the benzoxazine compound (C) excluding solvent, the amount of the bismaleimide resin (A) can be 20 parts by weight, 21 parts by weight, 22 parts by weight, 23 parts by weight, 24 parts by weight, 25 parts by weight, 26 parts by weight, 27 parts by weight, 28 parts by weight, 29 parts by weight, 30 parts by weight, 31 parts by weight, 32 parts by weight, 33 parts by weight, 34 parts by weight, 35 parts by weight, 36 parts by weight, 37 parts by weight, 38 parts by weight, 39 parts by weight, 40 parts by weight, 41 parts by weight, 42 parts by weight, 43 parts by weight, 44 parts by weight, 45 parts by weight, 46 parts by weight, 47 parts by weight, 48 parts by weight, 49 parts by weight, 50 parts by weight, 51 parts by weight, 52 parts by weight, 53 parts by weight, 54 parts by weight, 55 parts by weight, 56 parts by weight, 57 parts by weight, 58 parts by weight, 59 parts by weight, 60 parts by weight, 61 parts by weight, 62 parts by weight, 63 parts by weight, 64 parts by weight, 65 parts by weight, 66 parts by weight, 67 parts by weight, 68 parts by weight, 69 parts by weight, 70 parts by weight, 71 parts by weight, 72 parts by weight, 73 parts by weight, 74 parts by weight, 75 parts by weight, 76 parts by weight, 77 parts by weight, 78 parts by weight, 79 parts by weight, or 80 parts by weight, or within a range between any two of the values described herein. However, the present invention is not limited to the aforementioned ranges, and persons having ordinary skill in the art can adjust the amount depending on practical needs.

In the resin composition of the present invention, based on 100 wt % of the total weight of the resin composition excluding solvent, the amount of the bismaleimide resin (A) can be 10 wt % to 60 wt %. For example, based on 100 wt % of the total weight of the resin composition excluding solvent, the amount of the bismaleimide resin (A) can be 10 wt %, 11 wt %, 12 wt %, 13 wt %, 14 wt %, 15 wt %, 16 wt %, 17 wt %, 18 wt %, 19 wt %, 20 wt %, 21 wt %, 22 wt %, 23 wt %, 24 wt %, 25 wt %, 26 wt %, 27 wt %, 28 wt %, 29 wt %, 30 wt %, 31 wt %, 32 wt %, 33 wt %, 34 wt %, 35 wt %, 36 wt %, 37 wt %, 38 wt %, 39 wt %, 40 wt %, 41 wt %, 42 wt %, 43 wt %, 44 wt %, 45 wt %, 46 wt %, 47 wt %, 48 wt %, 49 wt %, 50 wt %, 51 wt %, 52 wt %, 53 wt %, 54 wt %, 55 wt %, 56 wt %, 57 wt %, 58 wt %, 59 wt %, or 60 wt %, or within a range between any two of the values described herein.

### 1.2. Cyanate Ester Resin (B)

As used herein, the cyanate ester resin (B) refers to a resin having one or more —OCN functional groups. In one embodiment of the present invention, the cyanate ester resin is a chemical substance derived from a bisphenol derivative or phenolic derivative, wherein the H of at least one hydroxyl group (—OH) of the bisphenol derivative or phenolic derivative is substituted by a cyano group (—C≡N) to form a —OCN functional group. Due to the —OCN functional group, the cyanate ester resin can form a trimer via a cross-linking reaction. Alternatively, the cyanate ester resin can form a network structure by participating in a cross-linking reaction with other components having unsaturated functional groups.

Specific examples of the cyanate ester resin (B) include, but are not limited to, 2,2-bis(4-cyanooxyphenyl) propane, 4,4′-ethylidene bisphenylenecyanate, 4,4′-dicyanooxybiphenyl, bis(4-cyanooxy-3,5-dimethylphenyl) methane, bis(4-cyanooxyphenyl) sulfide, bis(4-cyanooxyphenyl) ether, a prepolymer of bisphenol A dicyanate ester, 1,1-bis(4-cyanooxyphenyl) ethane, 1,1-bis(4-cyanooxyphenyl) methane, 1,3-bis(4-cyanooxyphenyl-1-(methylethylidene))benzene, bis(4-cyanooxyphenyl) ether, bis(4-cyanooxyphenyl)-2,2-butane, 1,3-bis[2-(4-cyanooxyphenyl) propyl]benzene, tris(4-cyanooxyphenyl) ethane, cyanated phenol, and an adduct of cyanated phenol dicyclopentadiene. The aforementioned cyanate ester resins can be used individually or in a mixture of two or more.

According to the present invention, the number average molecular weight (Mn) of the cyanate ester resin (B) is 1000 to 3000. That is, the number average molecular weight of the cyanate ester resin (B) is within a specific range. For example, the number average molecular weight of the cyanate ester resin (B) can be 1000, 1050, 1100, 1150, 1200, 1250, 1300, 1350, 1400, 1450, 1500, 1550, 1600, 1650, 1700, 1750, 1800, 1850, 1900, 1950, 2000, 2050, 2100, 2150, 2200, 2250, 2300, 2350, 2400, 2450, 2500, 2550, 2600, 2650, 2700, 2750, 2800, 2850, 2900, 2950, or 3000, or within a range between any two of the values described herein. By means of controlling the number average molecular weight of the cyanate ester resin (B) within the designated range, electronic materials obtained from the resin composition of the present invention can significantly improve their mechanical processing properties and also their multiple hot-pressing thermal resistance without compromising their Tg and thermal resistance. When the number average molecular weight of the cyanate ester resin (B) is higher or lower than the designated range, electronic materials obtained therefrom possess poor mechanical processing properties.

Commercially available cyanate ester resins include, but are not limited to, products such as TA 1000S (Mn ranges from 2500 to 3000) available from Yangzhou Techia New Material. In addition, the cyanate ester resin (B) may also be prepared as below. First, a cyanate ester monomer is dissolved in an organic solvent to obtain a homogeneous solution. Then, the homogeneous solution is placed in a nitrogen atmosphere and stirred at a temperature of 70° C. to 130° C. for 3 hours to 7 hours to perform a polymerization reaction. Afterwards, the organic solvent is removed by using a rotary evaporator to obtain a crude product. Then, the crude product is washed by methanol, followed by using a rotary evaporator to remove methanol to obtain a cyanate ester resin. Examples of the organic solvent include, but are not limited to, benzene, toluene, xylene, hexane, cyclohexane, heptane, decane, γ-butyrolactone, methyl ethyl ketone, Cyclohexanone, butanone, and acetone. The aforementioned organic solvents can be used individually or in a mixture of two or more. In the appended examples, toluene is used.

In the resin composition of the present invention, based on 100 parts by weight of the total weight of the bismaleimide resin (A), the cyanate ester resin (B) and the benzoxazine compound (C) excluding solvent, the amount of the cyanate ester resin (B) can be 15 parts by weight to 50 parts by weight. For example, based on 100 parts by weight of the total weight of the bismaleimide resin (A), the cyanate ester resin (B) and the benzoxazine compound (C) excluding solvent, the amount of the cyanate ester resin (B) can be 15 parts by weight, 16 parts by weight, 17 parts by weight, 18 parts by weight, 19 parts by weight, 20 parts by weight, 21 parts by weight, 22 parts by weight, 23 parts by weight, 24 parts by weight, 25 parts by weight, 26 parts by weight, 27 parts by weight, 28 parts by weight, 29 parts by weight, 30 parts by weight, 31 parts by weight, 32 parts by weight, 33 parts by weight, 34 parts by weight, 35 parts by weight, 36 parts by weight, 37 parts by weight, 38 parts by weight, 39 parts by weight, 40 parts by weight, 41 parts by weight, 42 parts by weight, 43 parts by weight, 44 parts by weight, 45 parts by weight, 46 parts by weight, 47 parts by weight, 48 parts by weight, 49 parts by weight, or 50 parts by weight, or within a range between any two of the values described herein. However, the present invention is not limited to the aforementioned ranges, and persons having ordinary skill in the art can adjust the amount depending on practical needs.

In the resin composition of the present invention, based on 100 wt % of the total weight of the resin composition excluding solvent, the amount of the cyanate ester resin (B) can be 7 wt % to 35 wt %. For example, based on 100 wt % of the total weight of the resin composition excluding solvent, the amount of the cyanate ester resin (B) can be 7 wt %, 8 wt %, 9 wt %, 10 wt %, 11 wt %, 12 wt %, 13 wt %, 14 wt %, 15 wt %, 16 wt %, 17 wt %, 18 wt %, 19 wt %, 20 wt %, 21 wt %, 22 wt %, 23 wt %, 24 wt %, 25 wt %, 26 wt %, 27 wt %, 28 wt %, 29 wt %, 30 wt %, 31 wt %, 32 wt %, 33 wt %, 34 wt %, or 35 wt %, or within a range between any two of the values described herein.

### 1.3. Benzoxazine Compound (C)

As used herein, the benzoxazine compound refers to a compound having at least one benzoxazine structure. The benzoxazine structure refers to a bicyclic heterocyclic compound fused from a benzene ring and an oxazine ring. In one embodiment of the present invention, the benzoxazine compound (C) can be prepared by reacting a phenolic hydroxy compound, a monoamine compound and formaldehyde in accordance with the following reaction formula (z).

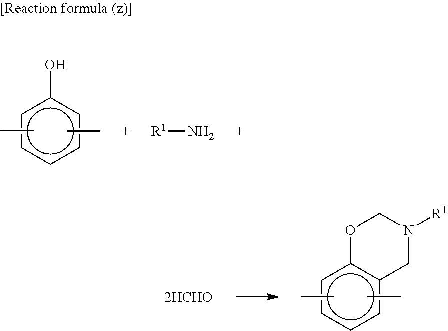

In the reaction formula (z), R₁ is alkyl, cycloalkyl, phenyl, alkyl-substituted phenyl group or alkoxy-substituted phenyl group. Examples of alkyl include, but are not limited to, methyl, ethyl, n-propyl, isopropyl, n-butyl, isobutyl, sec-butyl, tert-butyl, n-pentyl, isopentyl, neopentyl, n-hexyl, isohexyl, n-heptyl, isoheptyl, n-octyl, isooctyl, n-nonyl, isononyl, n-decyl, and isodecyl. Examples of cycloalkyl include, but are not limited to, cyclopropyl, cyclobutyl, cyclopentyl, cyclohexyl, cycloheptyl, cyclooctyl, cyclononyl, and cyclodecyl. Examples of alkoxy include, but are not limited to, methoxy, ethoxy, propoxy, butoxy, pentoxy, and hexoxy. Examples of the phenolic hydroxy compound can be polyfunctional phenols, biphenol compounds, bisphenol compounds, trisphenol compounds, and phenolic resins. Examples of polyfunctional phenols include, but are not limited to, catechol, resorcinol, and hydroquinone. Examples of bisphenol compounds include, but are not limited to, bisphenol A, bisphenol F, and bisphenol S. Examples of phenolic resins include but are not limited to novolac varnish resins and melamine phenolic resins. Examples of the monoamine compound include, but are not limited to, methylamine, aniline, alkyl-substituted aniline, and alkoxy-substituted aniline.

In one embodiment of the present invention, the benzoxazine compound (C) may also be as a benzoxazine prepolymer which undergoes a ring-opening reaction in advance. The preparation of the benzoxazine prepolymer does not constitute the core aspect of the present invention. The specific preparation of the benzoxazine prepolymer can be found in US 2012/0097437 A1, the subject matters of which are incorporated herein in their entirety by reference. The benzoxazine compound (C) may comprise one or more benzoxazine compounds. Commercially available benzoxazine compounds include, but are not limited to, products such as LZ 8280 available from Huntsman, PF-3500 available from Chang Chun Chemical, and JBZ-100N, JBZ-BF100N, and JBZ-BA100N available from JFE Chemicals.

In the resin composition of the present invention, based on 100 parts by weight of the total weight of the bismaleimide resin (A), the cyanate ester resin (B) and the benzoxazine compound (C) excluding solvent, the amount of the benzoxazine compound (C) can be 1 (one) part by weight to 15 parts by weight. For example, based on 100 parts by weight of the total weight of the bismaleimide resin (A), the cyanate ester resin (B) and the benzoxazine compound (C) excluding solvent, the amount of the benzoxazine compound (C) can be 1 (one) part by weight, 2 parts by weight, 3 parts by weight, 4 parts by weight, 5 parts by weight, 6 parts by weight, 7 parts by weight, 8 parts by weight, 9 parts by weight, 10 parts by weight, 11 parts by weight, 12 parts by weight, 13 parts by weight, 14 parts by weight, or 15 parts by weight, or within a range between any two of the values described herein. However, the present invention is not limited to the aforementioned ranges, and persons having ordinary skill in the art can adjust the amount depending on the need.

In the resin composition of the present invention, based on 100 wt % of the total weight of the resin composition excluding solvent, the amount of the benzoxazine compound (C) can be 1 wt % to 15 wt %. For example, based on 100 wt % of the total weight of the resin composition excluding solvent, the amount of the benzoxazine compound (C) can be 1 wt %, 2 wt %, 3 wt %, 4 wt %, 5 wt %, 6 wt %, 7 wt %, 8 wt %, 9 wt %, 10 wt %, 11 wt %, 12 wt %, 13 wt %, 14 wt %, or 15 wt %, or within a range between any two of the values described herein.

### 1.4. Optional Components

The resin composition of the present invention may further comprise optional components to adaptively improve the workability of the resin composition during processing or improve the physicochemical properties of the electronic material prepared from the resin composition. The optional components include, but are not limited to, various conventional additives known in the art, such as hardening accelerators, hardeners, fillers, dispersing agents, elastomers, tougheners, viscosity modifiers, flame retardants, and coupling agents, as well as other conventional thermosetting resins known in the art, such as epoxy resins, thermosetting polyphenylene ether resins, and thermosetting phenolic resins. The optional components do not constitute the core aspect of the present invention. They can be carried out by persons having ordinary skills in the art based on the disclosure of the subject specification and their skill level. The subsequent paragraphs elaborate on the optional components, focusing on hardening accelerators, hardeners, and fillers.

### [Hardening Accelerator]

The hardening accelerator can promote a hardening reaction, and lower the hardening reaction temperature of the resin composition. The type of the hardening accelerator is not particularly limited as long as it can promote a hardening reaction of the resin composition of the present invention and lower the hardening reaction temperature. In one embodiment of the present invention, the hardening accelerator is an imidazole compound, a pyridine compound, or a combination thereof. Examples of the imidazole compound include, but are not limited to, 2-methyl-imidazole (2 MI), 2-ethyl-4-methyl-imidazole (2E4MZ), and 2-phenyl-imidazole (2PI). The aforementioned imidazole compounds can be used individually or in a mixture of two or more. Examples of the pyridine compound include, but are not limited to, 2,3-diaminopyridine, 2,5-diaminopyridine, 2,6-diaminopyridine, 4-dimethylaminopyridine, 2-amino-3-methylpyridine, 2-amino-4-methylpyridine, and 2-amino-3-nitropyridine. The aforementioned pyridine compounds can be used individually or in a mixture of two or more. In the appended examples, 2PI is used.

The amount of the hardening accelerator can be adjusted depending on the need and is not particularly limited. Generally, based on 100 parts by weight of the total weight of the bismaleimide resin (A), the cyanate ester resin (B) and the benzoxazine compound (C) excluding solvent, the amount of the hardening accelerator can be 0 parts by weight to 0.5 parts by weight. For example, based on 100 parts by weight of the total weight of the bismaleimide resin (A), the cyanate ester resin (B) and the benzoxazine compound (C) excluding solvent, the amount of the hardening accelerator can 0.01 parts by weight, 0.05 parts by weight, 0.1 parts by weight, 0.15 parts by weight, 0.2 parts by weight, 0.25 parts by weight, 0.3 parts by weight, 0.35 parts by weight, 0.4 parts by weight, 0.45 parts by weight, or 0.5 parts by weight, or within a range between any two of the values described herein. However, the present invention is not limited to the aforementioned ranges, and persons having ordinary skill in the art can adjust the amount depending on the need.

### [Hardener]

The hardener has unsaturated functional group(s) and can undergo a crosslinking reaction with other components containing unsaturated functional group(s) (e.g., a bismaleimide resin, or a cyanate ester resin) to form a stereo network structure, thereby increasing the degree of crosslinking. The unsaturated functional group refers to a group capable of undergoing addition polymerization with other components containing unsaturated functional groups. Examples of the unsaturated group include, but are not limited to, vinyl, vinyl benzyl, allyl, acrylate group, and methacrylate group.

The types of the hardener are not particularly limited, and examples thereof include, but are not limited to, monovinyl-based compounds, multi-functional allyl-based compounds, multi-functional acrylates, multi-functional acrylamides, and multi-functional styrene-based compounds. The aforementioned hardeners can be used individually or in a mixture of two or more. In one embodiment of the present invention, the hardener is selected from the group consisting of styrene, α-methylstyrene, ethylstyrene, propylstyrene, butylstyrene, triallyl isocyanurate (TAIC), triallyl cyanurate (TAC), 1,3-divinylbenzene, 1,4-divinylbenzene, 1,2-bis(p-vinylphenyl) ethane, 1,2-bis(m-vinylphenyl) ethane, 1-(p-vinylphenyl)-2-(m-vinylphenyl) ethane, and combinations thereof.

The amount of the hardener can be adjusted depending on the need and is not particularly limited. Generally, based on 100 parts by weight of the total weight of the bismaleimide resin (A), the cyanate ester resin (B) and the benzoxazine compound (C) excluding solvent, the amount of the hardener can be 0 parts by weight to 10 parts by weight. For example, based on 100 parts by weight of the total weight of the bismaleimide resin (A), the cyanate ester resin (B) and the benzoxazine compound (C) excluding solvent, the amount of the hardener can be 0.1 parts by weight, 1 part by weight, 2 parts by weight, 3 parts by weight, 4 parts by weight, 5 parts by weight, 6 parts by weight, 7 parts by weight, 8 parts by weight, 9 parts by weight, or 10 parts by weight, or within a range between any two of the values described herein.

### [Filler]

The resin composition of the present invention can further comprise a filler to improve the mechanical strength, thermal conductivity and dimensional stability of the prepared electronic materials. Examples of suitable fillers include, but are not limited to, those selected from the group consisting of silica (including spherical silica, fused silica, non-fused silica, porous silica, hollow silica, and nano silica), aluminum oxide, magnesium oxide, magnesium hydroxide, calcium carbonate, talc, clay, aluminum nitride, boron nitride, aluminum hydroxide, silicon aluminum carbide, silicon carbide, sodium carbonate, titanium dioxide, zinc oxide, zirconium oxide, quartzes, diamond powder, diamond-like powder, graphite, calcined kaolin, pyran, mica, hydrotalcite, PTFE powder, glass bead, ceramic whisker, carbon nanotube, nanosized inorganic powder, and combinations thereof.

The amount of the filler can be adjusted depending on the need and is not particularly limited. Generally, based on 100 parts by weight of the total weight of the bismaleimide resin (A), the cyanate ester resin (B) and the benzoxazine compound (C) excluding solvent, the amount of the filler can be 50 parts by weight to 300 parts by weight. For example, based on 100 parts by weight of the total weight of the bismaleimide resin (A), the cyanate ester resin (B) and the benzoxazine compound (C) excluding solvent, the amount of the filler can be 50 parts by weight, 55 parts by weight, 60 parts by weight, 65 parts by weight, 70 parts by weight, 75 parts by weight, 80 parts by weight, 85 parts by weight, 90 parts by weight, 95 parts by weight, 100 parts by weight, 105 parts by weight, 110 parts by weight, 115 parts by weight, 120 parts by weight, 125 parts by weight, 130 parts by weight, 135 parts by weight, 140 parts by weight, 145 parts by weight, 150 parts by weight, 155 parts by weight, 160 parts by weight, 165 parts by weight, 170 parts by weight, 175 parts by weight, 180 parts by weight, 185 parts by weight, 190 parts by weight, 195 parts by weight, 200 parts by weight, 205 parts by weight, 210 parts by weight, 215 parts by weight, 220 parts by weight, 225 parts by weight, 230 parts by weight, 235 parts by weight, 240 parts by weight, 245 parts by weight, 250 parts by weight, 255 parts by weight, 260 parts by weight, 265 parts by weight, 270 parts by weight, 275 parts by weight, 280 parts by weight, 285 parts by weight, 290 parts by weight, 295 parts by weight, or 300 parts by weight, or within a range between any two of the values described herein.

### 1.5. Preparation of Resin Composition

Regarding the preparation of the resin composition of the present invention, the resin composition may be prepared into a slurry form for subsequent processing by uniformly mixing the components of the resin composition, including the bismaleimide resin (A), the cyanate ester resin (B) with a number average molecular weight ranging from 1000 to 3000, the benzoxazine compound (C), and other optional components, with a stirrer, and dissolving or dispersing the resultant mixture in a solvent. The solvent can be any inert solvent that can dissolve or disperse the components of the resin composition but does not react with the components of the resin composition. For example, solvents that can dissolve or disperse the components of the resin composition include, but are not limited to, toluene, γ-butyrolactone, methyl ethyl ketone, cyclohexanone, butanone, acetone, xylene, methyl isobutyl ketone, N,N-dimethylformamide (DMF), N,N-dimethylacetamide (DMAc), and N-methylpyrolidone (NMP). The aforementioned solvents can be used individually or in a mixture of two or more. The amount of the solvent in the resin composition is not particularly limited as long as the components of the resin composition can be evenly dissolved or dispersed therein. In the appended examples, methyl ethyl ketone is used as the solvent.

### 2. Uses of Resin Composition

The resin composition of the present invention can be used for preparing a prepreg, a metal-clad laminate and a printed circuit board. Thus, the present invention also provides a prepreg, a metal-clad laminate, and a printed circuit board prepared from the aforementioned resin composition.

### 2.1. Prepreg

The present invention also provides a prepreg prepared from the aforementioned resin composition. The prepreg is prepared by impregnating or coating a substrate with the aforementioned resin composition and drying the impregnated or coated substrate. The impregnating and coating methods include, but are not limited to, dipping, roller coating, die coating, bar coating, gravure coating, spin coating, slot-die coating, and spraying. The impregnated or coated substrate can be dried at 100° C. to 200° C. for 1 (one) minute to 20 minutes to obtain a prepreg in a semi-cured state (B-stage). In the appended examples, drying is performed at 175° C. for 2 minutes to 15 minutes.

The substrate can be any reinforcing material known in the field to which the present invention pertains. Generally, examples of the reinforcing material include, but are not limited to, spherical glass, and fibers selected from the group consisting of glass fibers, inorganic fibers other than glass fibers, organic fibers, and combinations thereof. Examples of the glass fibers include, but are not limited to, E-glass fibers, NE-glass fibers, S-glass fibers, L-glass fibers, D-glass fibers, T-glass fibers, Q-glass fibers, and UN-glass fibers. Examples of the inorganic fibers other than glass fibers include, but are not limited to, quartz fibers, paper fibers, and carbon fibers. Examples of the organic fibers include, but are not limited to, polyimide fibers, polyamide fibers (e.g., Kevlar fibers), polytetrafluoroethylene fibers, ultra-high molecular weight polyethylene (UHMWPE) fibers, high-modulus polypropylene (HMPP) fibers, and liquid crystal polymer (LCP) fibers. The form of the reinforcing material includes, but is not limited to, woven fabric, non-woven fabric, roving, chopped strand mat, and surfacing mat.

### 2.2. Metal-Clad Laminate

The present invention also provides a metal-clad laminate prepared from the aforementioned prepreg. The metal-clad laminate is prepared by laminating the aforementioned prepreg and a metal foil, wherein the prepreg serves as a dielectric layer, and the metal foil serves as a conductive layer. Alternatively, the metal-clad laminate of the present invention can be prepared by coating the aforementioned resin composition directly onto a metal foil and drying the coated metal foil, wherein the dried resin composition forms a dielectric layer, and the metal foil serves as a conductive layer.

In one embodiment of the present invention, the metal-clad laminate of the present invention can be prepared by the following way: superimposing a plurality of the aforementioned prepregs to provide a dielectric layer, then superimposing a metal foil (such as a copper foil, as the metal layer) on at least one external surface of the dielectric layer to provide a superimposed object comprising the dielectric layer and the metal layer, and performing a hot-pressing operation to the superimposed object to obtain the metal-clad laminate. The hot-pressing operation can be performed at a temperature of 180° C. to 240° C. and a full pressure of 10 kg/cm² to 25 kg/cm² (with an initial pressure of 5 kg/cm² to 12 kg/cm²) for 60 minutes to 240 minutes.

### 2.3. Printed Circuit Board

The metal-clad laminate of the present invention can be utilized to provide a printed circuit board by further patterning its metal foil. Therefore, the present invention also provides a printed circuit board, which is prepared by further patterning the metal foil of the metal-clad laminate of the present invention. The method for patterning the metal foil is not particularly limited. For example, the patterning method includes, but is not limited to, photolithography.

### 3. EXAMPLES

### 3.1. Testing Methods

The present invention is further illustrated by the specific examples hereinafter, wherein the testing instruments and methods are as follows.

### [Measurement of the Number Average Molecular Weight]

First, the cyanate ester resin is dissolved or diluted to form a test solution with a concentration of 0.5 mass %. Then, the number average molecular weight (Mn) of the cyanate ester resin is measured using a differential refractometer (model no.: HLC-8320GPC, available from Tosoh Corporation) in accordance with gel permeation chromatography (GPC). The measuring conditions are as follows: mobile phase is tetrahydrofuran, flow rate is 1 mL/min, column temperature is 30° C., columns are TSK Guardcolumn SuperHZ-L, TSK gel SuperHZM-N, TSK gel SuperHZM-M, and TSK gel SuperH-RC available from Tosoh Corporation in sequence, and molecular weight standard is monodispersed polystyrene.

### [Test of Upper Limit for the Number of Drilled Holes]

The test sample is prepared as follows. First, glass fiber cloths (model no.: 1078; thickness: 0.05 mm) are impregnated in the resin composition through a roll coater and the thicknesses of the impregnated glass fiber cloths are controlled to a proper extent. Subsequently, the impregnated glass fiber cloths undergo heating and drying in an oven at 175° C. for 2 minutes to 15 minutes, thereby producing in a semi-cured state (B-stage) prepregs (the resin content of the prepregs is about 52%). Each piece of the prepreg has a length of 33 cm and a width of 21.5 cm. Then, ten pieces of the prepreg are superimposed to obtain a five-layer superimposed object, wherein every two prepregs are pressed into one layer. Afterward, two sheets of ⅓-ounce copper foils are respectively placed on both of the two external surfaces of the superimposed object, followed by subjecting the resultant superimposed object with copper foils to a high-temperature hot-pressing curing process using a hot press machine. The high-temperature hot-pressing curing process is performed under the following conditions: heating to 200° C. to 220° C. at a heating rate of 2.0° C./min to 3.0° C./min, and hot-pressing at 200° C. to 220° C. for 180 minutes under a full pressure of 15 kg/cm² (an initial pressure is 8 kg/cm²). As a result, the test sample is prepared.

The test of upper limit for the number of drilled holes is performed as follows. First, a new drill bit with a blade length of 3.5 mm and a diameter of 0.1 mm (model no.: MCW 0.105×1.9 Z935MWU, available from UNION TOOL) is selected and mounted onto a drilling machine (model no.: super D6CMS, available from Suzhou Vega Technology). Then, the test sample is subjected to drilling processing on the drilling machine at a rotational speed of 195 krpm. When every 1000 holes are drilled, the drill bit is removed and observed using a microscope to check the wear level of the blade of the drill bit. When the wear ratio of the blade of the drill bit is greater than 20%, the number of drilled holes is recorded. The wear ratio is determined by observing the blade of the drill bit using a scanning electron microscope and calculating the ratio of the worn area of the blade to the total blade area using image analysis software. A higher number of drilled holes indicates better drilling performance.

### [Measurement of Glass Transition Temperature (Tg)]

The metal-clad laminate is etched to remove the metal foils on both sides, resulting in an unclad laminate. The unclad laminate undergoes a glass transition temperature (Tg) measurement. Specifically, the Tg of the unclad laminate is determined using a dynamic mechanical analyzer (model no.: Q800, available from TA Instruments) according to the following measuring conditions. A bending module is used, the frequency is 10 Hz, the heating rate is 5° C./min, and the dynamic viscoelasticity is measured during heating from room temperature to 280° C. The Tg is identified as the temperature at which tan δ in the resulting viscoelasticity curve reaches its maximum.

### [Test of Multiple Hot-Pressing Thermal Resistance]

The test sample is prepared as follows. First, glass fiber cloths (model no.: 1078; thickness: 0.05 mm) are impregnated in the resin composition through a roll coater and the thicknesses of the impregnated glass fiber cloths are controlled to a proper extent. Subsequently, the impregnated glass fiber cloths undergo heating and drying in an oven at 175° C. for 2 minutes to 15 minutes, thereby producing in a semi-cured state (B-stage) prepregs (the resin content of the prepregs is about 52%). Each piece of the prepregs has a length of 6.5 mm and a width of 6.5 mm. Then, six pieces of the prepregs are superimposed to obtain a superimposed object. Afterward, two sheets of ⅓-ounce copper foils are respectively placed on both of the two external surfaces of the superimposed object, thus obtaining the test sample.

The test of multiple hot-pressing thermal resistance is performed as follows. The test sample is placed in a hot press machine to undergo a high-temperature hot-pressing step several times. The high-temperature hot-pressing step is performed under the following conditions: heating to 190° C. to 200° C. at a heating rate of 3.0° C./min, and hot-pressing at 190° C. to 200° C. for 80 minutes to 100 minutes under a full pressure of 15 kg/cm² to 30 kg/cm² (an initial pressure was 8 kg/cm²). Upon completion of each high-temperature hot-pressing step, the surface of the test sample is observed to check if popcorn occurs due to bulging. If popcorn occurs, the hot-pressing ceased and the number of high-temperature hot-pressing steps at this point is recorded. If no popcorn occurs, testing continues with the next high-temperature hot-pressing step. When the number of high-temperature hot-pressing steps is greater, it indicates that the multiple hot-pressing thermal resistance of the metal-clad laminate is better.

### 3.2. List of Raw Materials

TABLE 1
List of raw materials

| Model no. | Description |
|---|---|
| BMI-2300 | Bismaleimide resin, available from Daiwa Kasei Industry |
| BMI-70 | Bismaleimide resin, available from Daiwa Kasei Industry |
| MIR-3000-70MT | Bismaleimide resin, available from Nippon Kayaku |
| JBZ-OP100N | Benzoxazine compound, available from JFE Chemicals |
| JBZ-BF100N | Benzoxazine compound, available from JFE Chemicals |
| JBZ-BA100N | Benzoxazine compound, available from JFE Chemicals |
| TA1000S | Cyanate ester resin (Mn is 2500 to 3000), available from Yangzhou Techia New |
| | Material |
| C01PS | Cyanate ester resin (Mn is 4000 to 40000), available from Yangzhou Techia |
| | New Material |
| CE01MO | Cyanate ester resin (Mn is 278), available from Yangzhou Techia New Material |
| C03CS | Cyanate ester resin (Mn is 350 to 400), available from Yangzhou Techia New |
| | Material |
| C05CS | Cyanate ester resin (Mn is 350 to 450), available from Yangzhou Techia New |
| | Material |
| C06MO | Cyanate ester resin (Mn is 306), available from Yangzhou Techia New Material |
| C09MO | Cyanate ester resin (Mn is 264), available from Yangzhou Techia New Material |
| CE07MO | Cyanate ester resin (Mn is 396), available from Yangzhou Techia New Material |
| SPB-100 | Flame retardant, available from Otsuka Chemical |
| XZ92741 | Flame retardant, available from BLUE CUBE (U.S.) |
| 2PI | Hardening accelerator, available from SHIKOKU CHEMICALS |
| 2E4MZ | Hardening accelerator, available from Sigma-Aldrich |
| NQ2035V | SiO₂ filler, available from Jiangsu NOVORAY New Material |
| Q099 | SiO₂ filler, available from Suzhou GINET New Material |
| 2214 | SiO₂ filler, available from Zhejiang Sanshi New Material Technology |

### 3.3. Synthesis of Cyanate Ester Resin

### Synthesis Example 1

First, 100 g of a cyanate ester monomer having the structure of the following formula (B-1) was dissolved in 30 g of toluene to obtain a homogeneous solution. Then, the homogeneous solution was placed in a nitrogen atmosphere and stirred at a temperature of 90° C. to 110° C. for 5 hours to carry out a polymerization reaction. Afterward, a crude product was obtained by removing toluene with a rotary evaporator, followed by washing the crude product with methanol several times. Then, cyanate ester resin 1 was obtained by removing methanol with a rotary evaporator. The Mn of cyanate ester resin 1 was measured using the aforementioned testing methods, and the result is 1500 to 2500.

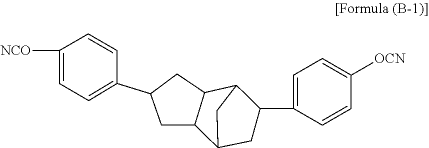

### Synthesis Example 2

First, 100 g of a cyanate ester monomer having the structure of the following formula (B-2) was dissolved in 30 g of toluene to obtain a homogeneous solution. Then, the homogeneous solution was placed in a nitrogen atmosphere and stirred at a temperature of 90° C. to 110° C. for 3 hours to carry out a polymerization reaction. Afterward, a crude product was obtained by removing toluene with a rotary evaporator, followed by washing the crude product with methanol several times. Then, cyanate ester resin 2 was obtained by removing methanol with a rotary evaporator. The Mn of cyanate ester resin 2 was measured using the aforementioned testing methods, and the result is 1500 to 2500.

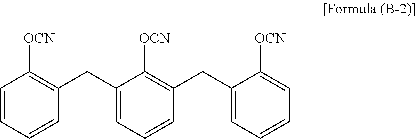

### Synthesis Example 3

First, 100 g of a cyanate ester monomer having the structure of the following formula (B-3) was dissolved in 30 g of toluene to obtain a homogeneous solution. Then, the homogeneous solution was placed in a nitrogen atmosphere and stirred at a temperature of 90° C. to 110° C. for 5 hours to carry out a polymerization reaction. Afterward, a crude product was obtained by removing toluene with a rotary evaporator, followed by washing the crude product with methanol several times. Then, cyanate ester resin 3 was obtained by removing methanol with a rotary evaporator. The Mn of cyanate ester resin 3 was measured using the aforementioned testing methods, and the result is 2100 to 2800.

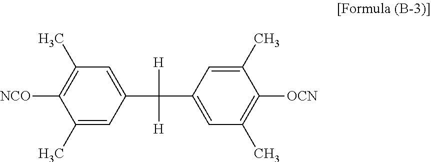

### Synthesis Example 4

First, 100 g of a cyanate ester monomer having the structure of the following formula (B-4) was dissolved in 30 g of toluene to obtain a homogeneous solution. Then, the homogeneous solution was placed in a nitrogen atmosphere and stirred at a temperature of 90° C. to 110° C. for 3 hours to carry out a polymerization reaction. Afterward, a crude product was obtained by removing toluene with a rotary evaporator, followed by washing the crude product with methanol several times. Then, cyanate ester resin 4 was obtained by removing methanol with a rotary evaporator. The Mn of cyanate ester resin 4 was measured using the aforementioned testing methods, and the result is 2500 to 3000.

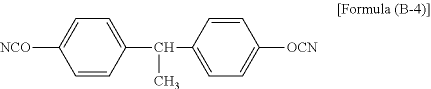

### Synthesis Example 5

First, 100 g of a cyanate ester monomer having the structure of the following formula (B-5) was dissolved in 30 g of toluene to obtain a homogeneous solution. Then, the homogeneous solution was placed in a nitrogen atmosphere and stirred at a temperature of 90° C. to 110° C. for 4 hours to carry out a polymerization reaction. Afterward, a crude product was obtained by removing toluene with a rotary evaporator, followed by washing the crude product with methanol several times. Then, cyanate ester resin 5 was obtained by removing methanol with a rotary evaporator. The Mn of cyanate ester resin 5 was measured using the aforementioned testing methods, and the result is 1500 to 2800.

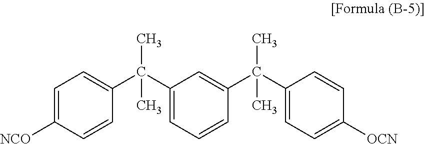

### Synthesis Example 6

First, 100 g of a cyanate ester monomer having the structure of the following formula (B-6) was dissolved in 30 g of toluene to obtain a homogeneous solution. Then, the homogeneous solution was placed in a nitrogen atmosphere and stirred at a temperature of 90° C. to 110° C. for 1 hour to carry out a polymerization reaction. Afterward, a crude product was obtained by removing toluene with a rotary evaporator, followed by washing the crude product with methanol several times. Then, cyanate ester resin 6 was obtained by removing methanol with a rotary evaporator. The Mn of cyanate ester resin 6 was measured using the aforementioned testing methods, and the result is 500 to 900.

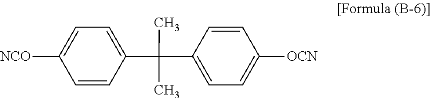

### Synthesis Example 7

First, 100 g of a cyanate ester monomer having the structure of the above formula (B-6) was dissolved in 30 g of toluene to obtain a homogeneous solution. Then, the homogeneous solution was placed in a nitrogen atmosphere and stirred at a temperature of 90° C. to 110° C. for 2 hours to carry out a polymerization reaction. Afterward, a crude product was obtained by removing toluene with a rotary evaporator, followed by washing the crude product with methanol several times. Then, cyanate ester resin 7 was obtained by removing methanol with a rotary evaporator. The Mn of cyanate ester resin 7 was measured using the aforementioned testing methods, and the result is 1100 to 1700.

### 3.4. Preparation of Resin Composition

The resin compositions of Examples 1 to 9 and Comparative Examples 1 to 10 were prepared according to the proportions shown in Table 2-1, Table 2-2, Table 2-3 and Table 2-4. Specifically, each of the resin compositions was prepared by mixing the components at room temperature with a stirrer, adding methyl ethyl ketone (available from Methyl Company) as a solvent, and stirring the resultant mixture at room temperature for 60 minutes to 120 minutes to obtain the resin composition. In Table 2-1, Table 2-2, Table 2-3 and Table 2-4, the parts by weight of each component are based on the weight excluding the solvent.

TABLE 2-1
Compositions of resin compositions of Examples of 1 to 5

| | | Example | | | | |
|---|---|---|---|---|---|---|
| Parts by weight | | 1 | 2 | 3 | 4 | 5 |
| Bismaleimide | BMI-2300 | 45 | | | 80 | 20 |
| resin (A) | BMI-70 | | 45 | | | |
| | MIR-3000-70MT | | | 45 | | |
| Cyanate ester | TA1000S | 45 | 45 | 45 | | |
| resin (B) | Cyanate ester resin 1 | | | | 15 | |
| | Cyanate ester resin 2 | | | | | 35 |
| Benzoxazine | JBZ-OP100N | 10 | | | 5 | 15 |
| compound (C) | JBZ-BF100N | | 10 | | | |
| | JBZ-BA100N | | | 10 | | |
| Hardening | 2PI | 0.01 | 0.01 | 0.01 | 0.01 | 0.01 |
| accelerator | | | | | | |
| Filler | NQ2035V | 100 | | | 100 | 100 |
| | Q099 | | 100 | | | |
| | 2214 | | | 100 | | |

TABLE 2-2
Compositions of resin compositions of Examples of 6 to 9

| | | Example | | | |
|---|---|---|---|---|---|
| Parts by weight | | 6 | 7 | 8 | 9 |
| Bismaleimide resin (A) | BMI-2300 | 35 | 45 | 45 | 45 |
| Cyanate ester resin (B) | Cyanate ester resin 3 | 50 | | | |
| | Cyanate ester resin 4 | | 45 | | |
| | Cyanate ester resin 5 | | | 45 | |
| | Cyanate ester resin 7 | | | | 45 |
| Benzoxazine compound (C) | JBZ-OP100N | 10 | 10 | 10 | 10 |
| Hardening accelerator | 2PI | 0.01 | 0.01 | 0.01 | 0.01 |
| Filler | NQ2035V | 100 | 100 | 300 | 100 |

TABLE 2-3
Compositions of resin compositions of Comparative Examples of 1 to 5

| | | Comparative Example | | | | |
|---|---|---|---|---|---|---|
| Parts by weight | | 1 | 2 | 3 | 4 | 5 |
| Bismaleimide resin (A) | BMI-2300 | | 50 | 45 | 45 | 45 |
| Cyanate ester resin (B) | TA1000S | 50 | 50 | | | |
| | C01PS | | | 45 | | |
| | CE01MO | | | | 45 | |
| | C03CS | | | | | 45 |
| Benzoxazine | JBZ-OP100N | 20 | | 10 | 10 | 10 |
| compound (C) | | | | | | |
| Hardening accelerator | 2PI | 0.01 | 0.01 | 0.01 | 0.01 | 0.01 |
| Filler | NQ2035V | 100 | 100 | 100 | 100 | 100 |

TABLE 2-4
Compositions of resin compositions of Comparative Examples of 6 to 10

| | | Comparative Example | | | | |
|---|---|---|---|---|---|---|
| Parts by weight | | 6 | 7 | 8 | 9 | 10 |
| Bismaleimide resin (A) | BMI-2300 | 45 | 45 | 45 | 45 | 45 |
| Cyanate ester resin (B) | C05CS | 45 | | | | |
| | C06MO | | 45 | | | |
| | C09MO | | | 45 | | |
| | CE07MO | | | | 45 | |
| | Cyanate ester | | | | | 45 |
| | resin 6 | | | | | |
| Benzoxazine | JBZ-OP100N | 10 | 10 | 10 | 10 | 10 |
| compound (C) | | | | | | |
| Hardening accelerator | 2PI | 0.01 | 0.01 | 0.01 | 0.01 | 0.01 |
| Filler | NQ2035V | 100 | 100 | 100 | 100 | 100 |

### 3.5. Preparation and Property Measurements of Prepreg and Metal-Clad Laminate

Prepregs and metal-clad laminates were prepared respectively by using the resin compositions of Examples 1 to 9 and Comparative Examples 1 to 10. First, glass fiber cloths (model no.: 1078; thickness: 0.05 mm) were impregnated in the resin compositions of Examples 1 to 9 and Comparative Examples 1 to 10 through a roll coater and the thicknesses of the impregnated glass fiber cloths were controlled to a proper extent. Subsequently, the impregnated glass fiber cloths underwent heating and drying in an oven at 175° C. for 2 minutes to 15 minutes, thereby producing in a semi-cured state (B-stage) prepregs (the resin content of the prepregs was about 52%). Then, several pieces of the prepreg were superimposed to obtain a superimposed object, two sheets of ⅓-ounce copper foils were respectively placed on both of the two external surfaces of the superimposed object, followed by subjecting the resultant superimposed object with copper foils to a high-temperature hot-pressing curing process using a hot press machine. The high-temperature hot-pressing curing process was performed under the following conditions: heating to 200° C. to 220° C. at a heating rate of 2.0° C./min to 3.0° C./min, and hot-pressing at 200° C. to 220° C. for 180 minutes under a full pressure of 15 kg/cm² (an initial pressure was 8 kg/cm²). As a result, metal-clad laminates of Examples 1 to 9 and Comparative Examples 1 to 10 were prepared.

The properties of the metal-clad laminates of Examples 1 to 9 and Comparative Examples 1 to 10, including Tg, upper limit for the number of drilled holes and multiple hot-pressing thermal resistance, were determined according to the aforementioned testing methods. The results are tabulated in Table 3-1 and Table 3-2.

TABLE 3-1
Properties of metal-clad laminates of Examples 1 to 9

| | | Upper limit for the number of | Multiple hot-pressing thermal |
|---|---|---|---|
| | Tg | drilled holes | resistance |
| Example 1 | 269° C. | 6000 holes | >60 times |
| Example 2 | 267° C. | 6000 holes | >60 times |
| Example 3 | 261° C. | 7000 holes | >60 times |
| Example 4 | 273° C. | 7000 holes | >60 times |
| Example 5 | 255° C. | 8000 holes | >60 times |
| Example 6 | 263° C. | 7000 holes | >60 times |
| Example 7 | 261° C. | 7000 holes | >60 times |
| Example 8 | 265° C. | 7000 holes | >60 times |
| Example 9 | 268° C. | 5000 holes | >60 times |

TABLE 3-2
Properties of metal-clad laminates of Comparative Examples 1 to 10

| | | Upper limit for the | Multiple hot-pressing |
|---|---|---|---|
| | Tg | number of drill holes | thermal resistance |
| Comparative Example 1 | 180° C. | 5000 holes | 2 times |
| Comparative Example 2 | 230° C. | 6000 holes | 5 times |
| Comparative Example 3 | 259° C. | 3000 holes | >60 times |
| Comparative Example 4 | 266° C. | 2000 holes | >60 times |
| Comparative Example 5 | 260° C. | 3000 holes | >60 times |
| Comparative Example 6 | 269° C. | 2000 holes | >60 times |
| Comparative Example 7 | 264° C. | 3000 holes | >60 times |
| Comparative Example 8 | 264° C. | 3000 holes | >60 times |
| Comparative Example 9 | 264° C. | 3000 holes | >60 times |
| Comparative Example 10 | 268° C. | 4000 holes | >60 times |

As shown in Table 3-1, the results of Examples 1 to 9 show that the metal-clad laminates prepared from the resin compositions of the present invention simultaneously exhibit high Tg, high upper limit for the number of drill holes, and excellent multiple hot-pressing thermal resistance (i.e., the number of cycles of hot-pressing exceeds 60). Specifically, Examples 1 to 3 demonstrate that, when the resin compositions comprise identical cyanate ester resin (B) (having a number average molecular weight (Mn) within the designated range), even when the types of the bismaleimide resin (A) and/or benzoxazine compound (C) are altered, the resultant metal-clad laminates can simultaneously exhibit high Tg, high upper limit for the number of drill holes, and excellent multiple hot-pressing thermal resistance. Examples 1 and 7 to 9 demonstrate that, when the resin compositions comprise identical bismaleimide resin (A) and benzoxazine compound (C), as long as the cyanate ester resin (B) has a Mn within the designated range, the resultant metal-clad laminates can simultaneously exhibit high Tg, high upper limit for the number of drill holes, and excellent multiple hot-pressing thermal resistance. Examples 4 to 6 further demonstrate that, even when the amounts of the bismaleimide resin (A), cyanate ester resin (B) and benzoxazine compound (C) in the resin composition are altered, as long as the amounts are within the range designated by the present invention, the resultant metal-clad laminate can simultaneously exhibit high Tg, high upper limit for the number of drill holes, and excellent multiple hot-pressing thermal resistance.

By contrast, as shown in Table 3-2, the metal-clad laminates prepared from the resin compositions outside the scope of the present invention do not simultaneously exhibit high Tg, high upper limit for the number of drill holes, and excellent multiple hot-pressing thermal resistance. Specifically, Comparative Examples 1 and 2 demonstrate that, if the resin compositions do not simultaneously comprise the bismaleimide resin (A), cyanate ester resin (B) and benzoxazine compound (C), the resultant metal-clad laminates exhibit low Tg and poor multiple hot-pressing thermal resistance. Comparative Examples 3 to 10 demonstrate that, if the cyanate ester resin (B) comprised in the resin composition does not have a Mn within the designated range, the resultant metal-clad laminate exhibits low upper limit for the number of drill holes, which is disadvantageous for subsequent processing.

The above examples are used to illustrate the principle and efficacy of the present invention and show the inventive features thereof, but are not used to limit the scope of the present invention. People skilled in this field may proceed with a variety of modifications and replacements based on the disclosures and suggestions of the invention as described. Therefore, the scope of protection of the present invention is that as defined in the claims as appended.

What is claimed is:

1. A resin composition, which comprises:
(A) a bismaleimide resin;
(B) a cyanate ester resin with a number average molecular weight ranging from 1000 to 3000; and
(C) a benzoxazine compound.

2. The resin composition of claim 1, wherein the bismaleimide resin (A) has a structure represented by the following formula (I): 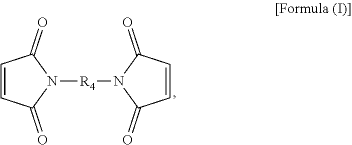
in formula (I), R₄ is selected from the group consisting of methylene (—CH₂—), 4,4′-diphenylmethane group 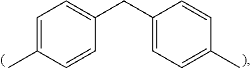
m-phenylene 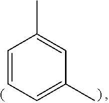
bisphenol A diphenyl ether group 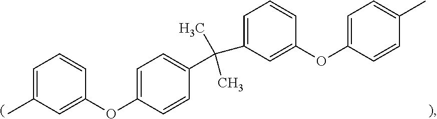
3,3′-dimethyl-5,5′-diethyl-4,4′-diphenylmethane group 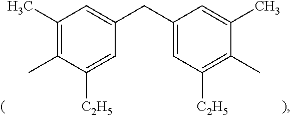
4-methyl-1,3-phenylene 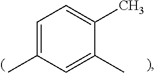
2,2,4-trimethyl-1,6-hexamethylene 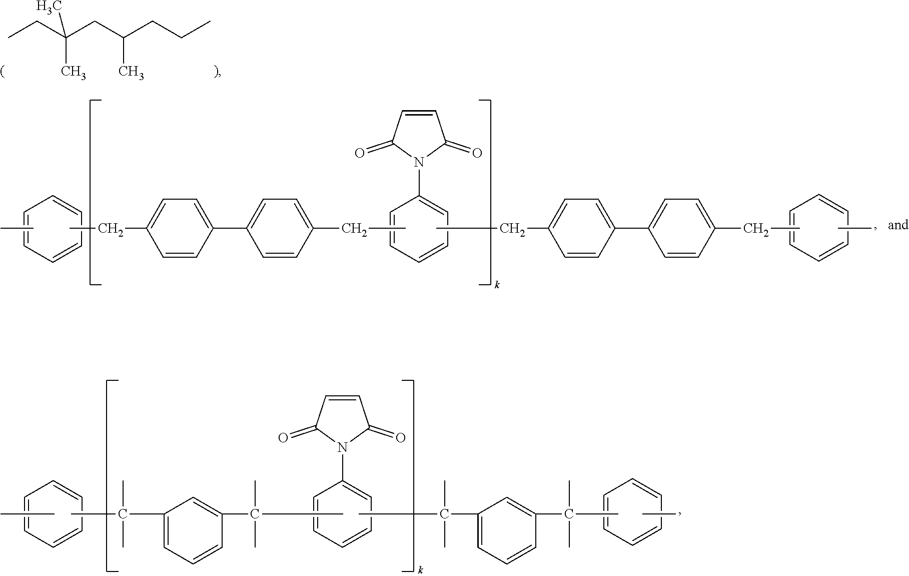
wherein k is an integer of 0 to 5.

3. The resin composition of claim 1, wherein the bismaleimide resin (A) is selected from the group consisting of 1,2-bismaleimidoethane, 1,6-bismaleimidohexane, 1,3-bismaleimidobenzene, 1,4-bismaleimidobenzene, 2,4-bismaleimidotoluene, 4,4′-bismaleimidodiphenylmethane, 4,4′-bismaleimidodiphenyl ether, 3,3′-bismaleimidodiphenyl sulfone, 4,4′-bismaleimidodiphenyl sulfone, 4,4′-bismaleimidodicyclohexylmethane, 3,5-bis(4-maleimidophenyl)pyridine, 2,6-bismaleimidopyridine, 1,3-bis(maleimidomethyl)cyclohexane, 1,3-bis(maleimidomethyl)benzene, 1,1-bis(4-maleimidophenyl)cyclohexane, 1,3-4,4′-biscitraconimidodiphenylmethane, 2,2-bis(4-bis(dichloromaleimido)benzene, maleimidophenyl) propane, 1-phenyl-1,1-bis(4-maleimidophenyl) ethane, α,α-bis(4-maleimidophenyl) toluene, 3,5-bismaleimido-1,2,4-triazole, N,N′-ethylenebismaleimide, N,N′-hexamethylenebismaleimide, N,N′-m-phenylenebismaleimide, N,N′-p-phenylenebismaleimide, N,N′-α,α′-4,4′-dimethylenecyclohexane bismaleimide, N,N′-m-dimethylphenylbismaleimide, N,N′-4,4′-diphenylcyclohexane bismaleimide, 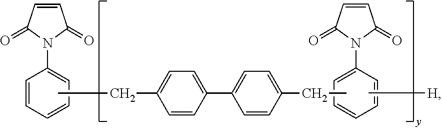
and combinations thereof,
wherein y is an integer of 1 to 4.

4. The resin composition of claim 1, wherein the cyanate ester resin (B) is selected from the group consisting of 2,2-bis(4-cyanooxyphenyl) propane, 4,4′-ethylidene bisphenylenecyanate, 4,4′-dicyanooxybiphenyl, bis(4-cyanooxy-3,5-dimethylphenyl) methane, bis(4-cyanooxyphenyl) sulfide, bis(4-cyanooxyphenyl) ether, a prepolymer of bisphenol A dicyanate ester, 1,1-bis(4-cyanooxyphenyl) ethane, 1,1-bis(4-cyanooxyphenyl) methane, 1,3-bis(4-cyanooxyphenyl-1-(methylethylidene))benzene, bis(4-cyanooxyphenyl) ether, bis(4-cyanooxyphenyl)-2,2-butane, 1,3-bis[2-(4-cyanooxyphenyl) propyl]benzene, tris(4-cyanooxyphenyl) ethane, cyanated phenol, an adduct of cyanated phenol dicyclopentadiene, and combinations thereof.

5. The resin composition of claim 1, further comprising a hardening accelerator selected from the group consisting of an imidazole compound, a pyridine compound, and a combination thereof.

6. The resin composition of claim 2, further comprising a hardening accelerator selected from the group consisting of an imidazole compound, a pyridine compound, and a combination thereof.

7. The resin composition of claim 3, further comprising a hardening accelerator selected from the group consisting of an imidazole compound, a pyridine compound, and a combination thereof.

8. The resin composition of claim 4, further comprising a hardening accelerator selected from the group consisting of an imidazole compound, a pyridine compound, and a combination thereof.

9. The resin composition of claim 1, further comprising a hardener selected from the group consisting of styrene, α-methylstyrene, ethylstyrene, propylstyrene, butylstyrene, triallyl isocyanurate (TAIC), triallyl cyanurate (TAC), 1,3-divinylbenzene, 1,4-divinylbenzene, 1,2-bis(p-vinylphenyl) ethane, 1,2-bis(m-vinylphenyl) ethane, 1-(p-vinylphenyl)-2-(m-vinylphenyl) ethane, and combinations thereof.

10. The resin composition of claim 2, further comprising a hardener selected from the group consisting of styrene, α-methylstyrene, ethylstyrene, propylstyrene, butylstyrene, triallyl isocyanurate (TAIC), triallyl cyanurate (TAC), 1,3-divinylbenzene, 1,4-divinylbenzene, 1,2-bis(p-vinylphenyl) ethane, 1,2-bis(m-vinylphenyl) ethane, 1-(p-vinylphenyl)-2-(m-vinylphenyl) ethane, and combinations thereof.

11. The resin composition of claim 3, further comprising a hardener selected from the group consisting of styrene, α-methylstyrene, ethylstyrene, propylstyrene, butylstyrene, triallyl isocyanurate (TAIC), triallyl cyanurate (TAC), 1,3-divinylbenzene, 1,4-divinylbenzene, 1,2-bis(p-vinylphenyl) ethane, 1,2-bis(m-vinylphenyl) ethane, 1-(p-vinylphenyl)-2-(m-vinylphenyl) ethane, and combinations thereof.

12. The resin composition of claim 4, further comprising a hardener selected from the group consisting of styrene, α-methylstyrene, ethylstyrene, propylstyrene, butylstyrene, triallyl isocyanurate (TAIC), triallyl cyanurate (TAC), 1,3-divinylbenzene, 1,4-divinylbenzene, 1,2-bis(p-vinylphenyl) ethane, 1,2-bis(m-vinylphenyl) ethane, 1-(p-vinylphenyl)-2-(m-vinylphenyl) ethane, and combinations thereof.

13. The resin composition of claim 1, further comprising a filler selected from the group consisting of silica, aluminum oxide, magnesium oxide, magnesium hydroxide, calcium carbonate, talc, clay, aluminum nitride, boron nitride, aluminum hydroxide, silicon aluminum carbide, silicon carbide, sodium carbonate, titanium dioxide, zinc oxide, zirconium oxide, quartzes, diamond powder, diamond-like powder, graphite, calcined kaolin, pyran, mica, hydrotalcite, polytetrafluoroethylene (PTFE) powder, glass bead, ceramic whisker, carbon nanotube, nanosized inorganic powder, and combinations thereof.

14. The resin composition of claim 2, further comprising a filler selected from the group consisting of silica, aluminum oxide, magnesium oxide, magnesium hydroxide, calcium carbonate, talc, clay, aluminum nitride, boron nitride, aluminum hydroxide, silicon aluminum carbide, silicon carbide, sodium carbonate, titanium dioxide, zinc oxide, zirconium oxide, quartzes, diamond powder, diamond-like powder, graphite, calcined kaolin, pyran, mica, hydrotalcite, polytetrafluoroethylene (PTFE) powder, glass bead, ceramic whisker, carbon nanotube, nanosized inorganic powder, and combinations thereof.

15. The resin composition of claim 3, further comprising a filler selected from the group consisting of silica, aluminum oxide, magnesium oxide, magnesium hydroxide, calcium carbonate, talc, clay, aluminum nitride, boron nitride, aluminum hydroxide, silicon aluminum carbide, silicon carbide, sodium carbonate, titanium dioxide, zinc oxide, zirconium oxide, quartzes, diamond powder, diamond-like powder, graphite, calcined kaolin, pyran, mica, hydrotalcite, polytetrafluoroethylene (PTFE) powder, glass bead, ceramic whisker, carbon nanotube, nanosized inorganic powder, and combinations thereof.

16. A prepreg, which is prepared by impregnating a substrate with the resin composition or by coating the resin composition of claim 1 onto a substrate and drying the impregnated or coated substrate.

17. A metal-clad laminate, which is prepared by laminating the prepreg of claim 16 and a metal foil.

18. A printed circuit board, which is prepared from the metal-clad laminate of claim 17.

19. A metal-clad laminate, which is prepared by coating the resin composition of claim 1 onto a metal foil and drying the coated metal foil.

20. A printed circuit board, which is prepared from the metal-clad laminate of claim 19.
